(19) United States
(12) Patent Application Publication
(10) Pub. No.: US 2024/0377546 A1
(43) Pub. Date: Nov. 14, 2024

(54) SYSTEMS AND METHODS FOR MODELING A SUBSURFACE VOLUME USING TIME-LAPSE DATA

(71) Applicant: Schlumberger Technology Corporation, Sugar Land, TX (US)

(72) Inventors: Wenyi Hu, Fulshear, TX (US); Aria Abubakar, Sugar Land, TX (US); Habibin Di, Houston, TX (US); Son D. Phan, Houston, TX (US)

(21) Appl. No.: 18/690,407

(22) PCT Filed: Sep. 15, 2022
(86) PCT No.: PCT/US2022/043663

§ 371 Date: Mar. 8, 2024

Related U.S. Application Data
(60) Provisional application No. 63/261,241, filed on Sep. 15, 2021.

(51) Int. Cl. G01V 1/28; G01V 1/30; G06F 30/27

(52) U.S. Cl. CPC G01V 1/282; G01V 1/307; G06F 30/27

(57) ABSTRACT

A method for modeling a subsurface volume using time-lapse data includes receiving a baseline seismic dataset, a baseline property model, a monitoring seismic dataset. and a monitoring property model. sorting the baseline seismic dataset and the monitoring seismic dataset into respective common gathers, representing offset, time, and depth point, extracting signal data for a range of depth points for the baseline dataset and a signal data for a corresponding range of depth points for the monitoring seismic dataset, predicting a property model change based at least in part on the signal data for the range of depth points of the baseline seismic dataset and the monitoring seismic dataset, using a machine learning model, and generating a property model representing a subsurface volume based at least in part on the property model change predicted using the machine learning model.

### CROSS-REFERENCE TO RELATED APPLICATIONS

This application claims priority to U.S. Provisional Patent Application Ser. No. 63/261,241, which was filed on 15 Sep. 2021 and is incorporated by reference herein in its entirety.

### BACKGROUND

Four-dimensional (4D) time lapse seismic data is used for reservoir monitoring, CO2 injection and storage monitoring, enhanced oil recovery (EOR) monitoring, and other applications. Design and implementation of time-lapse seismic surveys can be expensive and time-consuming and inefficiencies in the design may be generated.

### SUMMARY

Embodiments of the disclosure include a method for modeling a subsurface volume using time-lapse data, the method including receiving a baseline seismic dataset, a baseline property model, a monitoring seismic dataset, and a monitoring property model, sorting the baseline seismic dataset and the monitoring seismic dataset into respective common gathers, representing offset, time, and depth point, extracting signal data for a range of depth points for the baseline dataset and a signal data for a corresponding range of depth points for the monitoring seismic dataset, predicting a property model change based at least in part on the signal data for the range of depth points of the baseline seismic dataset and the monitoring seismic dataset, using a machine learning model, and generating a property model representing a subsurface volume based at least in part on the property model change predicted using the machine learning model.

Embodiments of the disclosure include a computing system including one or more processors, and a memory system comprising one or more non-transitory, computer-readable media storing instructions that, when executed by at least one of the one or more processors, cause the computing system to perform operations, the operations including receiving a baseline seismic dataset, a baseline property model, a monitoring seismic dataset, and a monitoring property model, sorting the baseline seismic dataset and the monitoring seismic dataset into respective common gathers, representing offset, time, and depth point, extracting signal data for a range of depth points for the baseline dataset and a signal data for a corresponding range of depth points for the monitoring seismic dataset, predicting a property model change based at least in part on the signal data for the range of depth points of the baseline seismic dataset and the monitoring seismic dataset, using a machine learning model, and generating a property model representing a subsurface volume based at least in part on the property model change predicted using the machine learning model.

Embodiments of the disclosure include a non-transitory, computer-readable medium storing instructions that, when executed by at least one processor of a computing system, cause the computing system to perform operations, the operations including receiving a baseline seismic dataset, a baseline property model, a monitoring seismic dataset, and a monitoring property model, sorting the baseline seismic dataset and the monitoring seismic dataset into respective common gathers, representing offset, time, and depth point, extracting signal data for a range of depth points for the baseline dataset and a signal data for a corresponding range of depth points for the monitoring seismic dataset, predicting a property model change based at least in part on the signal data for the range of depth points of the baseline seismic dataset and the monitoring seismic dataset, using a machine learning model, and generating a property model representing a subsurface volume based at least in part on the property model change predicted using the machine learning model.

### BRIEF DESCRIPTION OF THE DRAWINGS

The accompanying drawings, which are incorporated in and constitute a part of this specification, illustrate embodiments of the present teachings and together with the description, serve to explain the principles of the present teachings. In the figures:

FIGS. 1A, 1B, 1C, 1D, 2, 3A, and 3B illustrate simplified, schematic views of an oilfield and its operation, according to an embodiment.

FIG. 4 illustrates a flowchart of a method for CO2 and other subsurface property estimation using pre-migration time lapse monitoring data, according to an embodiment

FIG. 5 illustrates a conceptual view of a baseline dataset and a monitoring dataset, showing use of kinematic information for velocity model change estimation, according to an embodiment.

FIG. 6 illustrates another conceptual view of a baseline dataset and a monitoring dataset, showing use of amplitude change information for velocity model change estimation, according to an embodiment.

FIG. 7 illustrates a conceptual view of rearrangement of data to obtain common-midpoint gathers (CMPs), according to an embodiment.

FIG. 8 illustrates a conceptual view of arranging the data to fill up the whole volume for the purpose of subsequent label generation, according to an embodiment.

FIG. 9 illustrates a conceptual view of a workflow for generating ground truth labels for the network training, where the input is the kinematic information change or the amplitude change in the data domain and the output is the velocity (or another property) change in the model domain, according to an embodiment.

FIG. 10 illustrates a conceptual view of a workflow for training a convolution neural network (CNN) using labeled training data, according to an embodiment.

FIG. 11 illustrates a conceptual view of a workflow for predicting the velocity change corresponding to any new monitoring data using the trained convolutional neural network, according to an embodiment.

FIG. 12 illustrates a conceptual view of another workflow for label generation, according to an embodiment.

FIG. 13 illustrates a conceptual view of another workflow for network training, according to an embodiment.

FIG. 14 illustrates a conceptual view of another workflow for network testing, according to an embodiment.

FIG. 15 illustrates a schematic view of a computing system, according to an embodiment.

### DESCRIPTION OF EMBODIMENTS

Reference will now be made in detail to embodiments, examples of which are illustrated in the accompanying drawings and figures. In the following detailed description, numerous specific details are set forth in order to provide a thorough understanding of the invention. However, it will be apparent to one of ordinary skill in the art that the invention may be practiced without these specific details. In other instances, well-known methods, procedures, components, circuits and networks have not been described in detail so as not to unnecessarily obscure aspects of the embodiments.

It will also be understood that, although the terms first, second, etc. may be used herein to describe various elements, these elements should not be limited by these terms. These terms are only used to distinguish one element from another. For example, a first object could be termed a second object, and, similarly, a second object could be termed a first object, without departing from the scope of the invention. The first object and the second object are both objects, respectively, but they are not to be considered the same object.

The terminology used in the description of the invention herein is for the purpose of describing particular embodiments only and is not intended to be limiting of the invention. As used in the description of the invention and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

Attention is now directed to processing procedures, methods, techniques and workflows that are in accordance with some embodiments. Some operations in the processing procedures, methods, techniques and workflows disclosed herein may be combined and/or the order of some operations may be changed.

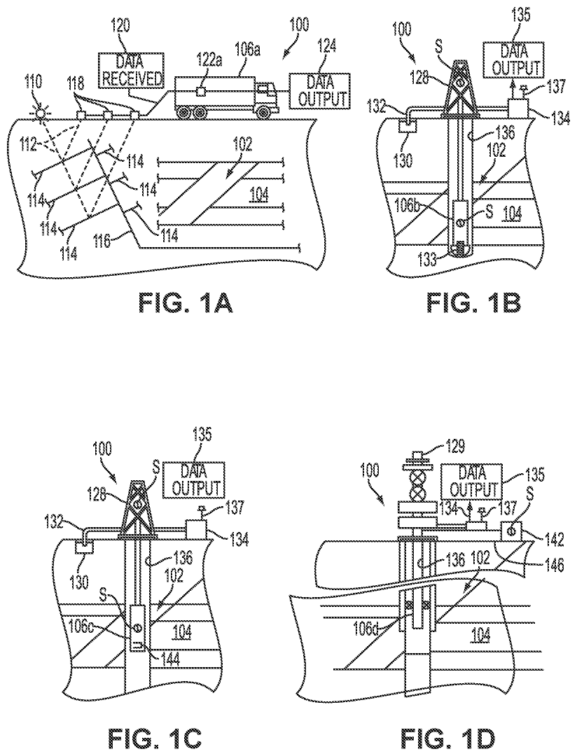

FIGS. 1A-1D illustrate simplified, schematic views of oilfield 100 having subterranean formation 102 containing reservoir 104 therein in accordance with implementations of various technologies and techniques described herein. FIG. 1A illustrates a survey operation being performed by a survey tool, such as seismic truck 106.1, to measure properties of the subterranean formation. The survey operation is a seismic survey operation for producing sound vibrations. In FIG. 1A, one such sound vibration, e.g., sound vibration 112 generated by source 110, reflects off horizons 114 in earth formation 116. A set of sound vibrations is received by sensors, such as geophone-receivers 118, situated on the earth's surface. The data received 120 is provided as input data to a computer 122.1 of a seismic truck 106.1, and responsive to the input data, computer 122.1 generates seismic data output 124. This seismic data output may be stored, transmitted or further processed as desired, for example, by data reduction.

FIG. 1B illustrates a drilling operation being performed by drilling tools 106.2 suspended by rig 128 and advanced into subterranean formations 102 to form wellbore 136. Mud pit 130 is used to draw drilling mud into the drilling tools via flow line 132 for circulating drilling mud down through the drilling tools, then up wellbore 136 and back to the surface. The drilling mud is typically filtered and returned to the mud pit. A circulating system may be used for storing, controlling, or filtering the flowing drilling mud. The drilling tools are advanced into subterranean formations 102 to reach reservoir 104. Each well may target one or more reservoirs. The drilling tools are adapted for measuring downhole properties using logging while drilling tools. The logging while drilling tools may also be adapted for taking core sample 133 as shown.

Computer facilities may be positioned at various locations about the oilfield 100 (e.g., the surface unit 134) and/or at remote locations. Surface unit 134 may be used to communicate with the drilling tools and/or offsite operations, as well as with other surface or downhole sensors. Surface unit 134 is capable of communicating with the drilling tools to send commands to the drilling tools, and to receive data therefrom. Surface unit 134 may also collect data generated during the drilling operation and produce data output 135, which may then be stored or transmitted.

Sensors(S), such as gauges, may be positioned about oilfield 100 to collect data relating to various oilfield operations as described previously. As shown, sensor (S) is positioned in one or more locations in the drilling tools and/or at rig 128 to measure drilling parameters, such as weight on bit, torque on bit, pressures, temperatures, flow rates, compositions, rotary speed, and/or other parameters of the field operation. Sensors (S) may also be positioned in one or more locations in the circulating system.

Drilling tools 106.2 may include a bottom hole assembly (BHA) (not shown), generally referenced, near the drill bit (e.g., within several drill collar lengths from the drill bit). The bottom hole assembly includes capabilities for measuring, processing, and storing information, as well as communicating with surface unit 134. The bottom hole assembly further includes drill collars for performing various other measurement functions.

The bottom hole assembly may include a communication subassembly that communicates with surface unit 134. The communication subassembly is adapted to send signals to and receive signals from the surface using a communications channel such as mud pulse telemetry, electro-magnetic telemetry, or wired drill pipe communications. The communication subassembly may include, for example, a transmitter that generates a signal, such as an acoustic or electromagnetic signal, which is representative of the measured drilling parameters. It will be appreciated by one of skill in the art that a variety of telemetry systems may be employed, such as wired drill pipe, electromagnetic or other known telemetry systems.

Typically, the wellbore is drilled according to a drilling plan that is established prior to drilling. The drilling plan typically sets forth equipment, pressures, trajectories and/or other parameters that define the drilling process for the wellsite. The drilling operation may then be performed according to the drilling plan. However, as information is gathered, the drilling operation may need to deviate from the drilling plan. Additionally, as drilling or other operations are performed, the subsurface conditions may change. The earth model may also need adjustment as new information is collected

The data gathered by sensors (S) may be collected by surface unit 134 and/or other data collection sources for analysis or other processing. The data collected by sensors (S) may be used alone or in combination with other data. The data may be collected in one or more databases and/or transmitted on or offsite. The data may be historical data, real time data, or combinations thereof. The real time data may be used in real time, or stored for later use. The data may also be combined with historical data or other inputs for further analysis. The data may be stored in separate databases, or combined into a single database.

Surface unit 134 may include transceiver 137 to allow communications between surface unit 134 and various portions of the oilfield 100 or other locations. Surface unit 134 may also be provided with or functionally connected to one or more controllers (not shown) for actuating mechanisms at oilfield 100. Surface unit 134 may then send command signals to oilfield 100 in response to data received. Surface unit 134 may receive commands via transceiver 137 or may itself execute commands to the controller. A processor may be provided to analyze the data (locally or remotely), make the decisions and/or actuate the controller. In this manner, oilfield 100 may be selectively adjusted based on the data collected. This technique may be used to optimize (or improve) portions of the field operation, such as controlling drilling, weight on bit, pump rates, or other parameters. These adjustments may be made automatically based on computer protocol, and/or manually by an operator. In some cases, well plans may be adjusted to select optimum (or improved) operating conditions, or to avoid problems.

FIG. 1C illustrates a wireline operation being performed by wireline tool 106.3 suspended by rig 128 and into wellbore 136 of FIG. 1B. Wireline tool 106.3 is adapted for deployment into wellbore 136 for generating well logs, performing downhole tests and/or collecting samples. Wireline tool 106.3 may be used to provide another method and apparatus for performing a seismic survey operation. Wireline tool 106.3 may, for example, have an explosive, radioactive, electrical, or acoustic energy source 144 that sends and/or receives electrical signals to surrounding subterranean formations 102 and fluids therein.

Wireline tool 106.3 may be operatively connected to, for example, geophones 118 and a computer 122.1 of a seismic truck 106.1 of FIG. 1A. Wireline tool 106.3 may also provide data to surface unit 134. Surface unit 134 may collect data generated during the wireline operation and may produce data output 135 that may be stored or transmitted. Wireline tool 106.3 may be positioned at various depths in the wellbore 136 to provide a survey or other information relating to the subterranean formation 102.

Sensors (S), such as gauges, may be positioned about oilfield 100 to collect data relating to various field operations as described previously. As shown, sensor S is positioned in wireline tool 106.3 to measure downhole parameters which relate to, for example porosity, permeability, fluid composition and/or other parameters of the field operation.

FIG. 1D illustrates a production operation being performed by production tool 106.4 deployed from a production unit or Christmas tree 129 and into completed wellbore 136 for drawing fluid from the downhole reservoirs into surface facilities 142. The fluid flows from reservoir 104 through perforations in the casing (not shown) and into production tool 106.4 in wellbore 136 and to surface facilities 142 via gathering network 146.

Sensors (S), such as gauges, may be positioned about oilfield 100 to collect data relating to various field operations as described previously. As shown, the sensor (S) may be positioned in production tool 106.4 or associated equipment, such as Christmas tree 129, gathering network 146, surface facility 142, and/or the production facility, to measure fluid parameters, such as fluid composition, flow rates, pressures, temperatures, and/or other parameters of the production operation.

Production may also include injection wells for added recovery. One or more gathering facilities may be operatively connected to one or more of the wellsites for selectively collecting downhole fluids from the wellsite(s).

While FIGS. 1B-1D illustrate tools used to measure properties of an oilfield, it will be appreciated that the tools may be used in connection with non-oilfield operations, such as gas fields, mines, aquifers, storage or other subterranean facilities. Also, while certain data acquisition tools are depicted, it will be appreciated that various measurement tools capable of sensing parameters, such as seismic two-way travel time, density, resistivity, production rate, etc., of the subterranean formation and/or its geological formations may be used. Various sensors (S) may be located at various positions along the wellbore and/or the monitoring tools to collect and/or monitor the desired data. Other sources of data may also be provided from offsite locations.

The field configurations of FIGS. 1A-1D are intended to provide a brief description of an example of a field usable with oilfield application frameworks. Part of, or the entirety, of oilfield 100 may be on land, water and/or sea. Also, while a single field measured at a single location is depicted, oilfield applications may be utilized with any combination of one or more oilfields, one or more processing facilities and one or more wellsites.

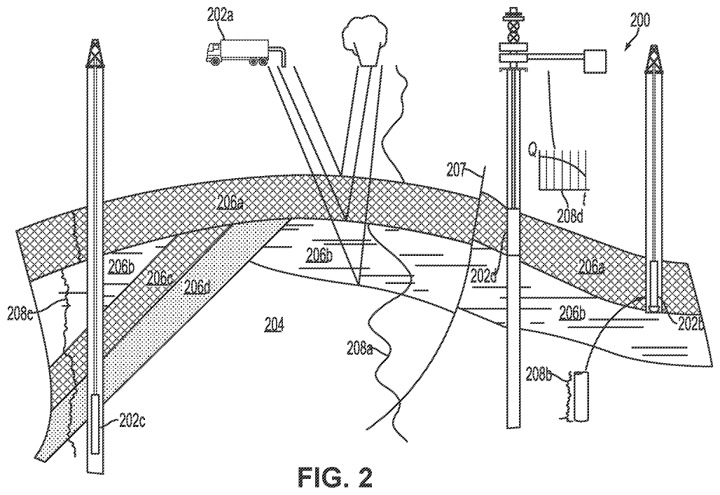

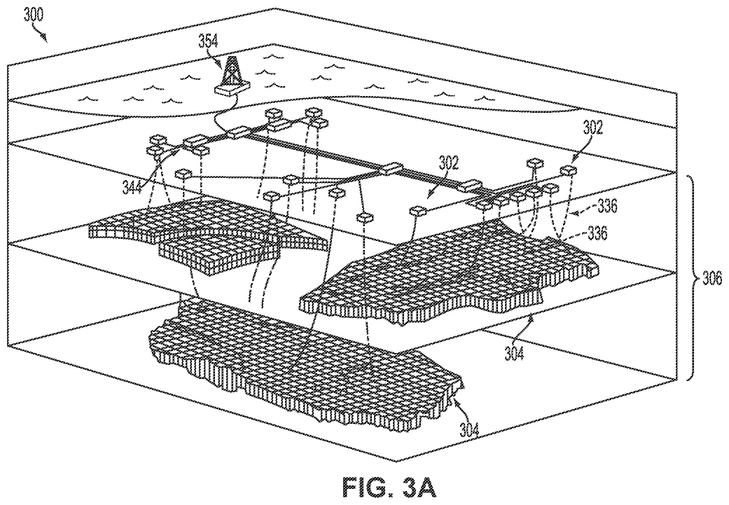

FIG. 2 illustrates a schematic view, partially in cross section of oilfield 200 having data acquisition tools 202.1, 202.2, 202.3 and 202.4 positioned at various locations along oilfield 200 for collecting data of subterranean formation 204 in accordance with implementations of various technologies and techniques described herein. Data acquisition tools 202.1-202.4 may be the same as data acquisition tools 106.1-106.4 of FIGS. 1A-1D, respectively, or others not depicted. As shown, data acquisition tools 202.1-202.4 generate data plots or measurements 208.1-208.4, respectively. These data plots are depicted along oilfield 200 to demonstrate the data generated by the various operations.

Data plots 208.1-208.3 are examples of static data plots that may be generated by data acquisition tools 202.1-202.3, respectively; however, it should be understood that data plots 208.1-208.3 may also be data plots that are updated in real time. These measurements may be analyzed to better define the properties of the formation(s) and/or determine the accuracy of the measurements and/or for checking for errors. The plots of each of the respective measurements may be aligned and scaled for comparison and verification of the properties.

Static data plot 208.1 is a seismic two-way response over a period of time. Static plot 208.2 is core sample data measured from a core sample of the formation 204. The core sample may be used to provide data, such as a graph of the density, porosity, permeability, or some other physical property of the core sample over the length of the core. Tests for density and viscosity may be performed on the fluids in the core at varying pressures and temperatures. Static data plot 208.3 is a logging trace that typically provides a resistivity or other measurement of the formation at various depths.

A production decline curve or graph 208.4 is a dynamic data plot of the fluid flow rate over time. The production decline curve typically provides the production rate as a function of time. As the fluid flows through the wellbore, measurements are taken of fluid properties, such as flow rates, pressures, composition, etc.

Other data may also be collected, such as historical data, user inputs, economic information, and/or other measurement data and other parameters of interest. As described below, the static and dynamic measurements may be analyzed and used to generate models of the subterranean formation to determine characteristics thereof. Similar measurements may also be used to measure changes in formation aspects over time.

The subterranean structure 204 has a plurality of geological formations 206.1-206.4. As shown, this structure has several formations or layers, including a shale layer 206.1, a carbonate layer 206.2, a shale layer 206.3 and a sand layer 206.4. A fault 207 extends through the shale layer 206.1 and the carbonate layer 206.2. The static data acquisition tools are adapted to take measurements and detect characteristics of the formations.

While a specific subterranean formation with specific geological structures is depicted, it will be appreciated that oilfield 200 may contain a variety of geological structures and/or formations, sometimes having extreme complexity. In some locations, typically below the water line, fluid may occupy pore spaces of the formations. Each of the measurement devices may be used to measure properties of the formations and/or its geological features. While each acquisition tool is shown as being in specific locations in oilfield 200, it will be appreciated that one or more types of measurement may be taken at one or more locations across one or more fields or other locations for comparison and/or analysis.

The data collected from various sources, such as the data acquisition tools of FIG. 2, may then be processed and/or evaluated. Typically, seismic data displayed in static data plot 208.1 from data acquisition tool 202.1 is used by a geophysicist to determine characteristics of the subterranean formations and features. The core data shown in static plot 208.2 and/or log data from well log 208.3 are typically used by a geologist to determine various characteristics of the subterranean formation. The production data from graph 208.4 is typically used by the reservoir engineer to determine fluid flow reservoir characteristics. The data analyzed by the geologist, geophysicist and the reservoir engineer may be analyzed using modeling techniques.

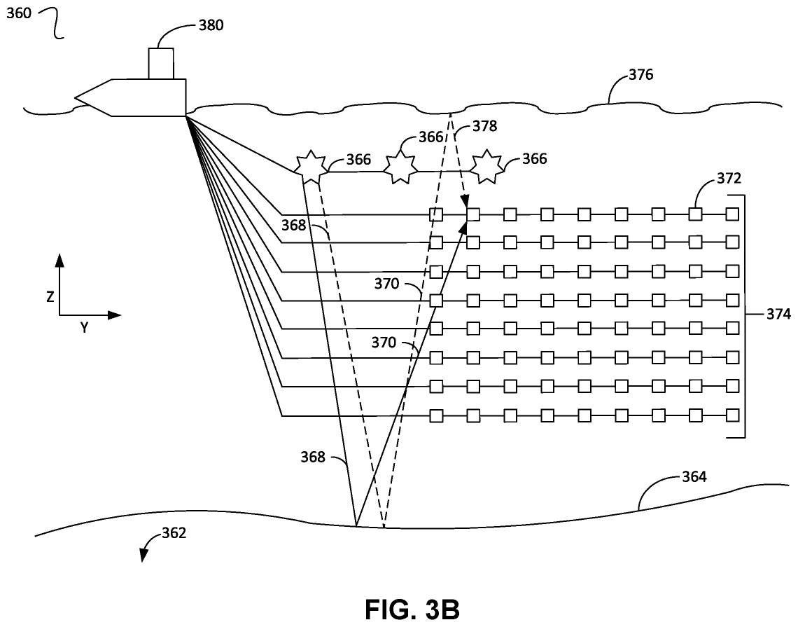

FIG. 3A illustrates an oilfield 300 for performing production operations in accordance with implementations of various technologies and techniques described herein. As shown, the oilfield has a plurality of wellsites 302 operatively connected to central processing facility 354. The oilfield configuration of FIG. 3A is not intended to limit the scope of the oilfield application system. Part, or all, of the oilfield may be on land and/or sea. Also, while a single oilfield with a single processing facility and a plurality of wellsites is depicted, any combination of one or more oilfields, one or more processing facilities and one or more wellsites may be present.

Each wellsite 302 has equipment that forms wellbore 336 into the earth. The wellbores extend through subterranean formations 306 including reservoirs 304. These reservoirs 304 contain fluids, such as hydrocarbons. The wellsites draw fluid from the reservoirs and pass them to the processing facilities via surface networks 344. The surface networks 344 have tubing and control mechanisms for controlling the flow of fluids from the wellsite to processing facility 354.

Attention is now directed to FIG. 3B, which illustrates a side view of a marine-based survey 360 of a subterranean subsurface 362 in accordance with one or more implementations of various techniques described herein. Subsurface 362 includes seafloor surface 364. Seismic sources 366 may include marine sources such as vibroseis or airguns, which may propagate seismic waves 368 (e.g., energy signals) into the Earth over an extended period of time or at a nearly instantaneous energy provided by impulsive sources. The seismic waves may be propagated by marine sources as a frequency sweep signal. For example, marine sources of the vibroseis type may initially emit a seismic wave at a low frequency (e.g., 5 Hz) and increase the seismic wave to a high frequency (e.g., 80-90 Hz) over time.

The component(s) of the seismic waves 368 may be reflected and converted by seafloor surface 364 (i.e., reflector), and seismic wave reflections 370 may be received by a plurality of seismic receivers 372. Seismic receivers 372 may be disposed on a plurality of streamers (i.e., streamer array 374). The seismic receivers 372 may generate electrical signals representative of the received seismic wave reflections 370. The electrical signals may be embedded with information regarding the subsurface 362 and captured as a record of seismic data.

In one implementation, each streamer may include streamer steering devices such as a bird, a deflector, a tail buoy and the like, which are not illustrated in this application. The streamer steering devices may be used to control the position of the streamers in accordance with the techniques described herein.

In one implementation, seismic wave reflections 370 may travel upward and reach the water/air interface at the water surface 376, a portion of reflections 370 may then reflect downward again (i.e., sea-surface ghost waves 378) and be received by the plurality of seismic receivers 372. The sea-surface ghost waves 378 may be referred to as surface multiples. The point on the water surface 376 at which the wave is reflected downward is generally referred to as the downward reflection point.

The electrical signals may be transmitted to a vessel 380 via transmission cables, wireless communication or the like. The vessel 380 may then transmit the electrical signals to a data processing center. Alternatively, the vessel 380 may include an onboard computer capable of processing the electrical signals (i.e., seismic data). Those skilled in the art having the benefit of this disclosure will appreciate that this illustration is highly idealized. For instance, surveys may be of formations deep beneath the surface. The formations may typically include multiple reflectors, some of which may include dipping events, and may generate multiple reflections (including wave conversion) for receipt by the seismic receivers 372. In one implementation, the seismic data may be processed to generate a seismic image of the subsurface 362.

Marine seismic acquisition systems tow each streamer in streamer array 374 at the same depth (e.g., 5-10 m). However, marine based survey 360 may tow each streamer in streamer array 374 at different depths such that seismic data may be acquired and processed in a manner that avoids the effects of destructive interference due to sea-surface ghost waves. For instance, marine-based survey 360 of FIG. 3B illustrates eight streamers towed by vessel 380 at eight different depths. The depth of each streamer may be controlled and maintained using the birds disposed on each streamer.

Time-lapse seismic data has widespread application in reservoir surveillance and CO2 monitoring. Time-lapse seismic data generally includes a baseline dataset and one or more monitoring datasets, which may, for example, represent a volume later-in-time than the baseline dataset. Although the following disclosure refers to a single monitoring dataset, it will be readily appreciated that several monitoring datasets could be used. A velocity model may be a component for subsurface imaging and property estimation, and accurate representations of the velocity model may be beneficial for enhancing CO2 monitoring reliability, and thus may be an example of a CO2 property model. Other examples of CO2 property models can include density, acoustic impedance, shear wave velocity, and saturation. The present disclosure may also be applied to other types of property models, such as density, acoustic impedance, and/or saturation models. There are at least two main depth velocity model building technologies, velocity tomography and full waveform inversion. Tomography may be complex and time-consuming. FWI may call for extensive, non-standard manual work for real field data, and may also be computationally expensive.

Embodiments of the present disclosure may provide a more efficient and convenient solution for seismic velocity model building in time lapse projects. For example, property (E.g., velocity) estimation may be performed from raw, pre-migration monitoring seismic data. Direct velocity model estimation may be accomplished without migration, tomography, or full waveform inversion processes. Although embodiments of the disclosure are discussed with respect to seismic signals, it will be appreciated that other types of signals may be employed. For example, non-seismic measurements such as electromagnetic (x-well EM, CSEM, MT, Surface to borehole electromagnetic), and gravity signals may also be employed. Further, x-well seismic, vertical seismic profile, DAS, and other seismic signals may be employed, consistent with at least some embodiments of the present disclosure.

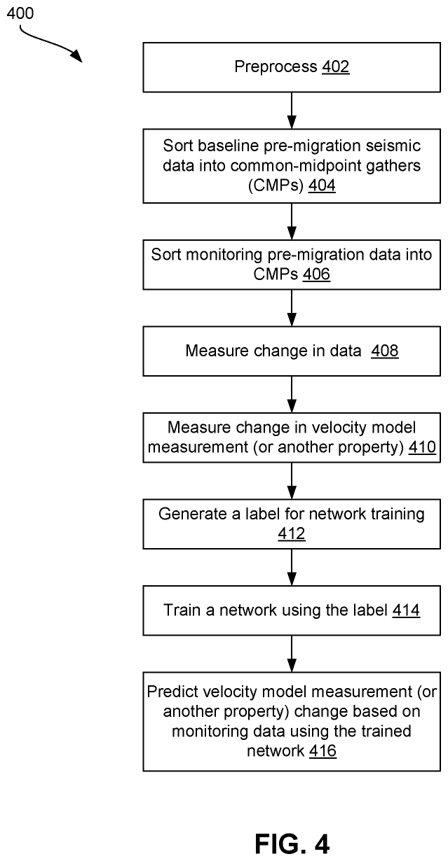

FIG. 4 illustrates a flowchart of a method 400 for modeling a subsurface volume using time-lapse data, e.g., using pre-migration time lapse monitoring data, according to an embodiment. The method 400 may include receiving and preprocessing input data, as at 402. The input may be a baseline dataset and a corresponding velocity model (or another subsurface property model), and a monitoring dataset and corresponding velocity model(s) (or another subsurface property model).

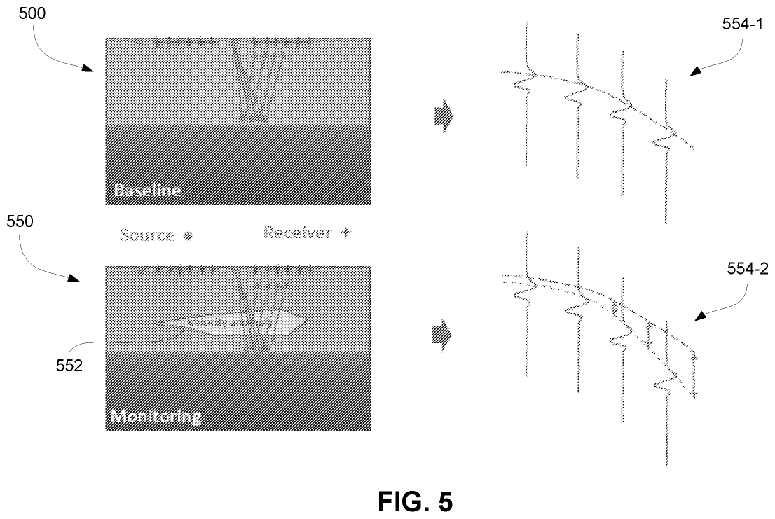

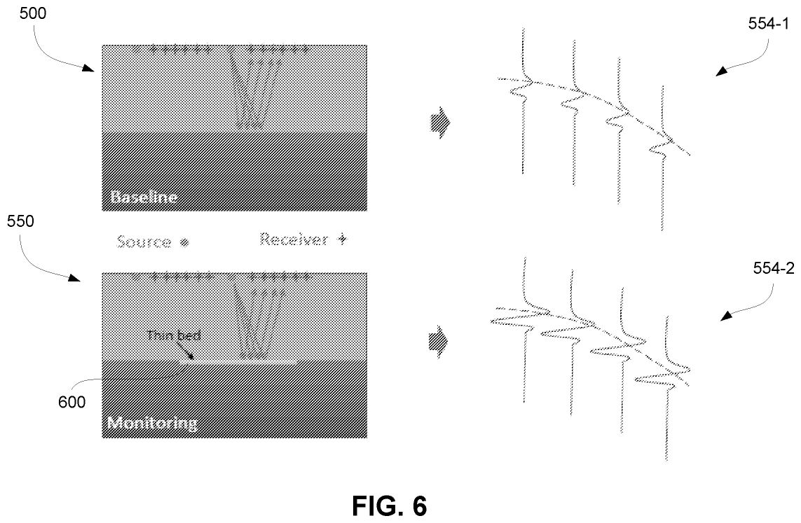

FIGS. 5 and 6 illustrate examples of such a baseline dataset 500 and a monitoring dataset 550, according to an embodiment. The baseline dataset (representing a subsurface volume) 500 may provide a useful baseline of the environment prior to or otherwise without the introduction of the velocity anomaly. Subsequently, the monitoring dataset 550 may be acquired, representing the same subsurface volume, e.g., in which a velocity anomaly 552 is now present (e.g., a CO2 plume), which was not present in the baseline dataset 500. Signals 554-1 correspond to the baseline dataset 500, and signals 554-2 correspond to the monitoring dataset 550. As a consequence of traveling through the velocity anomaly 552, the signals 554-2 may show a time shift, squeezing, stretching, etc. as compared to the signals 554-1. This may provide kinematic information (e.g., a time-shift map) that can be used for velocity model change estimation, as will be discussed in greater detail below. Similarly, the monitoring environment 550 in FIG. 6 includes a thin bed anomaly 600, which also changes the properties of the signals 554-2. For example, the signals 554-2 may show an amplitude change, as well as a small (e.g., undetectable) time-shift with respect to the signals 554-1. The amplitude information may thus be used for velocity model change estimation, despite the small/undetectable time shift.

Preprocessing at 402 may include denoising, amplitude balancing, bandwidth matching of attributes of the baseline data and the monitoring data, such that the two datasets are made closer. Preprocessing may also include data regularization, spectral shaping for bandwidth matching, trace weighting, data interpolation, late arrival energy boosting, thresholding, etc. Interpolation may also be implemented to make source and receiver geometry of the baseline data and the monitoring data similar (or the same). Further, such interpolation may be to make source and receiver spatial distribution more uniform. Preprocessing may be performed if data repeatability is relatively low, e.g., for amplitude change information extraction.

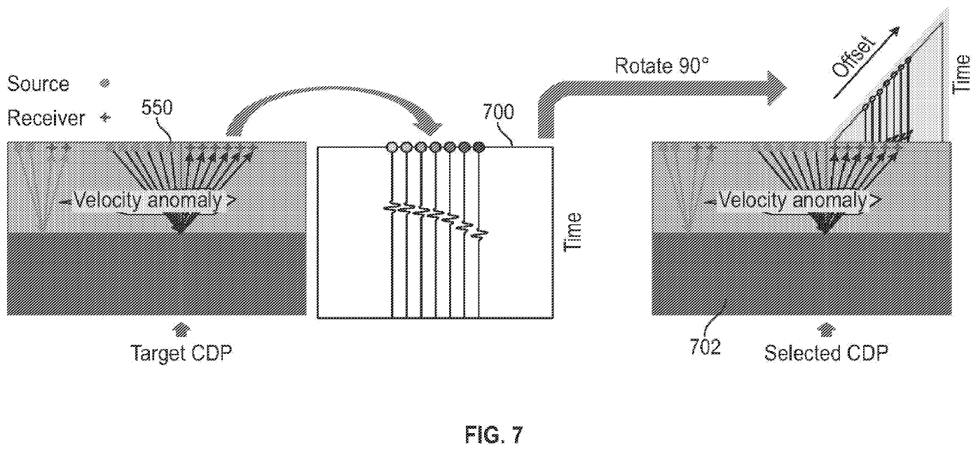

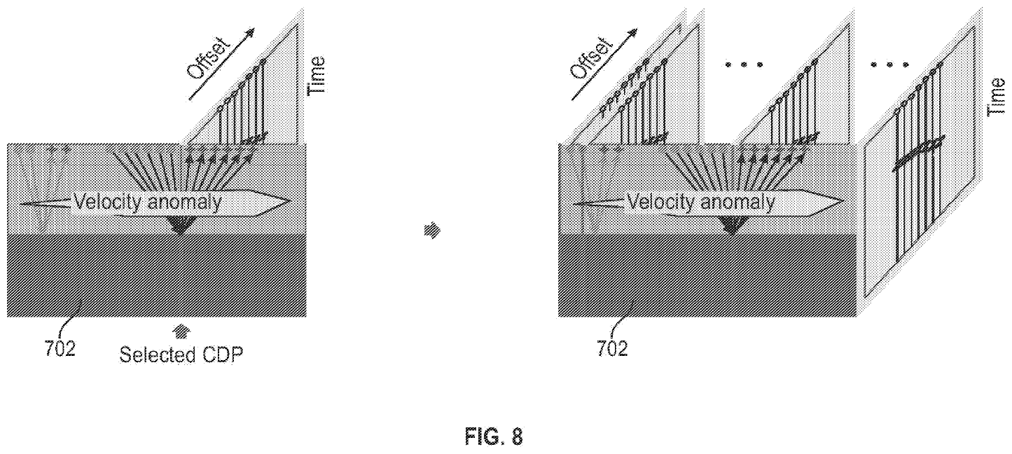

The method 400 may also include sorting the baseline pre-migration seismic data into a common midpoint gather (CMP) or multiple CMPs, as at 404. Although CMPs are discussed herein, it will be appreciated that other gathers, such as common offset gathers, common shot gathers, common receiver gathers, and other suitable gathers may be implemented. The method 400 may further include sorting monitoring pre-migration data into CMPs (or other gathers, as noted above), as at 406 (e.g., according to the example shown in FIGS. 7 and 8). The resulting dataset may be arranged in a 3D volume, where the vertical axis is time, the horizontal axis is a depth point, e.g., a common depth point (CDP) number, and the axis (into/out of the paper) is the offset. Thus, for example, each CMP gather may correspond to a specific CDP number in the velocity model, or a certain range of CMP gathers may correspond to a specific range of CDP lines in the velocity (or other type of subsurface property) model.

A CMP example is illustrated in FIG. 7. As shown, the monitoring dataset 550 (which may apply equally to the baseline dataset) may be rearranged into three-dimensional cube. In particular, for a given CDP, a two-dimensional slice of data 700, representing an offset and time, can be “rotated” (conceptually) into alignment along the CDP axis. The resulting dataset cube 702, as shown, may have the vertical axis being time, the x-axis being CDP number, and the y-axis (into/out of the paper) being the offset. A conceptual view of the completed cube 702 is illustrated in FIG. 8, according to an embodiment. Thus, each CMP gather may, for example, correspond to a specific CDP number in the velocity model.

The method 400 may also include measuring a change of a seismic signal characteristic (seismic signal data) as between the monitoring datasets over the baseline datasets for corresponding portions, e.g., CDP ranges, as at 408. For each monitoring dataset, the kinematic change (i.e., time shift) may be measured with respect to the baseline data. This is also conceptually illustrated in FIGS. 5 and 6. For those monitoring datasets with undetectable (or very slight) kinematic change, the amplitude (and/or envelope) change may be measured. The data change measurements are arranged into 3D volumes as at 404/406. Depending on the embodiment, time shift and/or amplitude change in monitoring data may be selected for velocity (or other property) model prediction.

The method 400 may further include measuring velocity model (or another subsurface property) changes corresponding to the same portions of the subsurface volume as the measured differences between the monitoring and baseline datasets, as at 410. For example, the baseline velocity model (or another subsurface property model represented in the baseline data) may be subtracted from the monitoring velocity model (or other property model represented by the monitoring dataset). In this case, both the baseline velocity model and the velocity model at the time the monitoring dataset was acquired are known, and thus their differences can be readily determined.

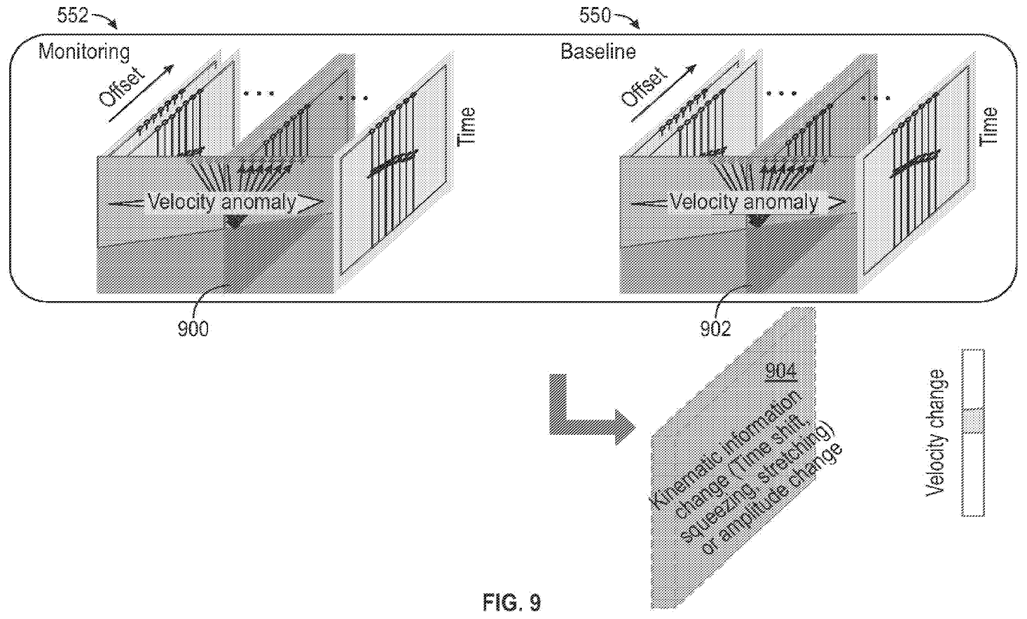

One or more labels may then be generated based on the changes measured in 408 and 410, as at 412. This is conceptually illustrated in FIG. 9, according to an embodiment. As shown, corresponding portions 900, 902 of seismic data representing the same CDP ranges in the monitoring and baseline dataset cubes 550, 552 (e.g., formed into cubes, as noted above) may be compared. From this comparison, time shift, squeezing, stretching, etc., may be obtained using deep learning, dynamic time warping, etc., and/or other kinematic properties may be compared, as indicated by 904. This property comparison 904 may be labeled with the velocity model change for this same portion, which may serve as a ground truth during a process for training a machine learning model (e.g., deep learning network, convolutional neural network, other types of networks, and/or other types of artificial intelligence). Next, in at least some embodiments, a portion of the data change measurements within the same CDP range may be extracted. This procedure results in a pair of labels for the network training i.e., the velocity model change and the data change for the CDP range. This procedure is repeated until many pairs of labels are generated across different CDP ranges, relating the differences in the datasets with the differences in the velocity models.

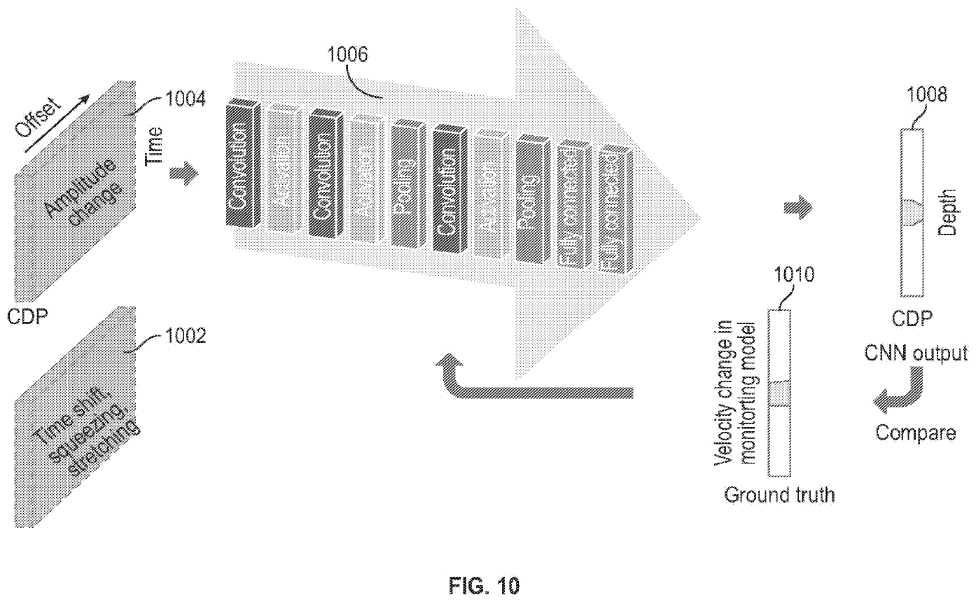

The machine learning model (any type of artificial intelligence) may then be trained using the generated labels, as at 414. This is conceptually illustrated in FIG. 10, according to an embodiment. That is, the input may be the dataset changes (e.g., time shift 1002 and/or amplitude changes 1004 for the seismic data in the portion of the gather). The dataset changes 1002, 1004 may be fed to the machine learning model 1006, which produces a velocity model change 1008. This may be compared to the known/measured velocity model change 1010. The differences (residual) therebetween may be back-propagated to the machine learning model 1006 in order to adjust the parameters of the machine learning model 1006, such that subsequent predictions result in a prediction 1008 that is closer to the ground truth 1010.

In some instances, the number of training labels may not be sufficient, in which case, synthetic training data may be generated, along with labels, by forward modeling, for example. In such an embodiment, the velocity model for the synthetic data may be built based on the baseline model and the augmented monitoring model. In some embodiments, the training data may be similar to the implementation data, and thus supervised learning may be employed. In other embodiments, other types of deep learning may be employed.

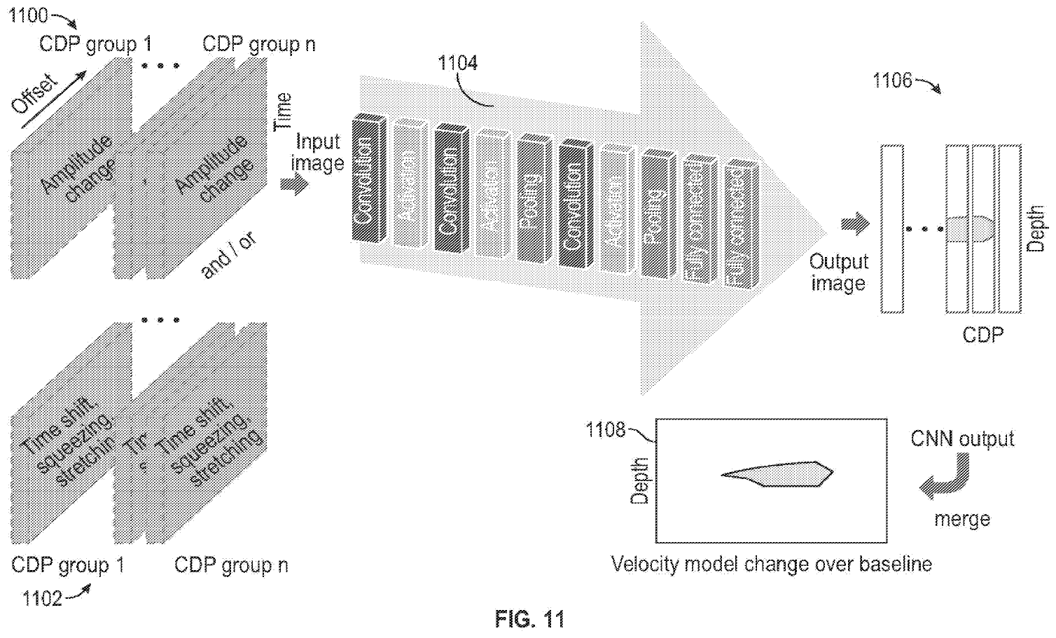

Referring again to FIG. 4, network inferencing may then be conducted, as at 416. For a given monitoring dataset, as shown in FIG. 11, blocks 406 and 408 may be implemented to obtain the monitoring data change for portions 1100, 1102 (e.g., amplitude and time shift, respectively) over a plurality of discrete portions of the common gather of the monitoring data, with respect to the baseline data. Then the data change measurements for the portions 1100, 1102 may be fed to the trained machine learning model (e.g., neural network) 1102. The output of the machine learning model 1004 may include predicted velocity model changes (or other subsurface property change) 1106 for successive portions, corresponding to the input portions 1100, 1102. Eventually, these outputs may be merged together to construct a new velocity model (or other subsurface property model) 1110. This velocity model 1110, which is generated more efficiently and/or accurately than past velocity models (or other property models) may then be employed to create CO2 monitoring project designs. For example, embodiments of the present disclosure can be adapted for CO2 plume body prediction from pre-migration monitoring data without image processing. In other words, if the network output is replaced with plume body change while keeping the input the same (in FIG. 9), the plume body change may be directly predicted using the pre-migration monitoring data without implementing the seismic imaging procedure. That is, instead of predicting the velocity model change, the plume body change may be predicted within the same framework as discussed above.

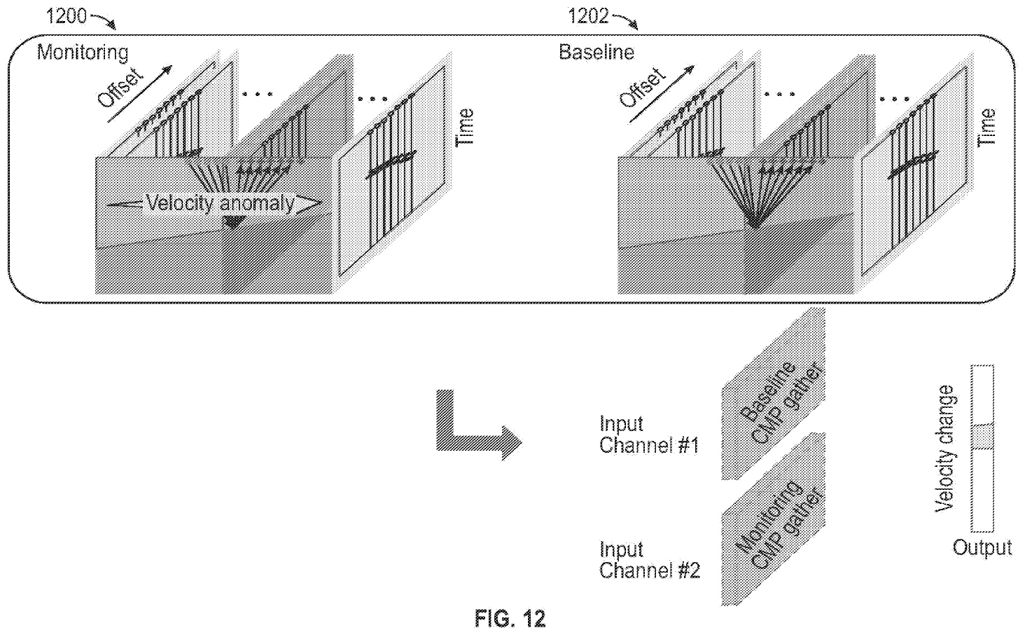

FIGS. 12-14 illustrate another embodiment of the method disclosed herein. This embodiment may be similar to those embodiments discussed above; however, the difference between the monitoring data and the baseline data may not be extracted. Instead, the monitoring data and baseline data may be provided to the network as two separate input channels. The output of the network may be the same as discussed above, e.g., velocity (or another property) change.

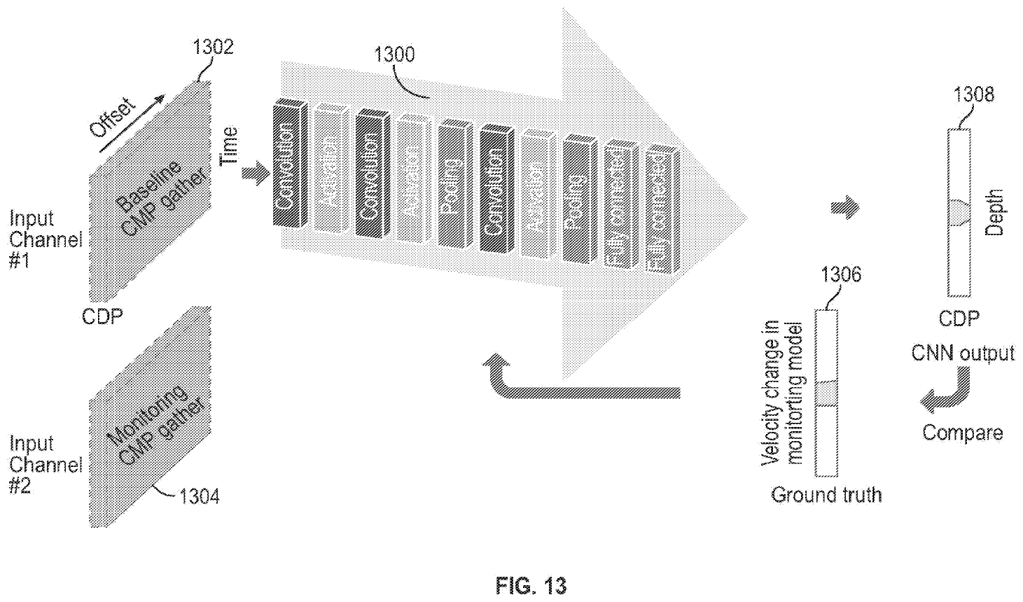

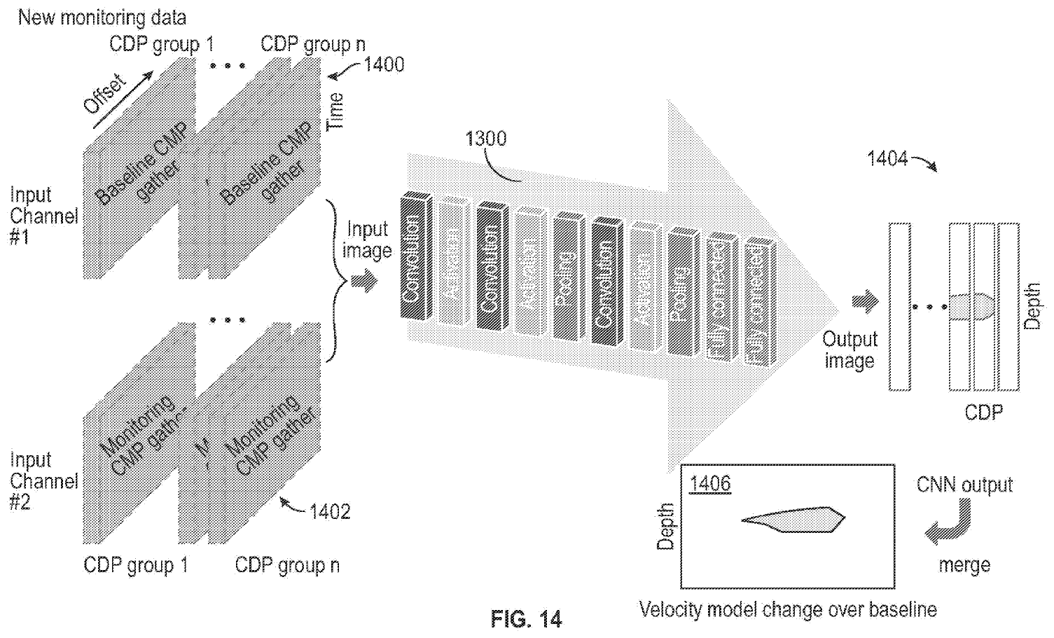

Turning again to the drawings, in FIG. 12, there is shown, for example, a monitoring dataset 1200 and a baseline dataset 1202, each arranged into a cube representing time, offset, and CDP, as discussed above. Portions of the baseline gather 1202 (e.g., a common midpoint gather (CMP)) and the monitoring CMP 1200 gather may be extracted as two input channels 1302, 1304 (e.g., multiple portions of each, e.g., as ranges of CDPs) to generate a pair of labels, e.g., with the velocity model for the corresponding portions. The network 1300 may then be trained, as shown in FIG. 13, using both channels 1302, 1304, e.g., by comparing the ground truth 1306 with the output of the neural network 1308. As shown in FIG. 14, the network 1300 may be tested (or implemented) using new monitoring data, in which the baseline CMP gathers 1400 and the monitoring CMP gathers 1402 are provided together to the trained network 1300, which generates an output image 1404 of CDP and depth, which may then be merged to find a velocity model change 1406 from the baseline velocity (or another property) model.

In one or more embodiments, the functions described can be implemented in hardware, software, firmware, or any combination thereof. For a software implementation, the techniques described herein can be implemented with modules (e.g., procedures, functions, subprograms, programs, routines, subroutines, modules, software packages, classes, and so on) that perform the functions described herein. A module can be coupled to another module or a hardware circuit by passing and/or receiving information, data, arguments, parameters, or memory contents. Information, arguments, parameters, data, or the like can be passed, forwarded, or transmitted using any suitable means including memory sharing, message passing, token passing, network transmission, and the like. The software codes can be stored in memory units and executed by processors. The memory unit can be implemented within the processor or external to the processor, in which case it can be communicatively coupled to the processor via various means as is known in the art.

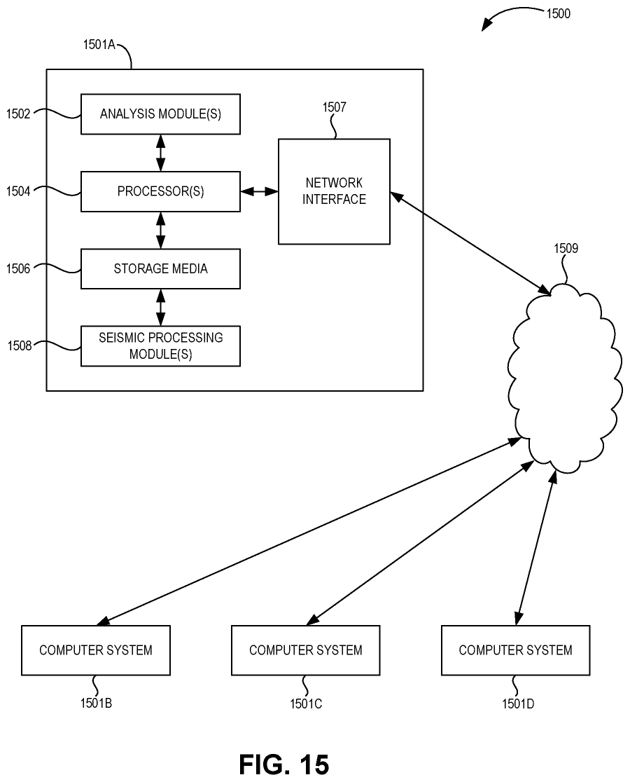

In some embodiments, any of the methods of the present disclosure may be executed by a computing system. FIG. 15 illustrates an example of such a computing system 1500, in accordance with some embodiments. The computing system 1500 may include a computer or computer system 1501A, which may be an individual computer system 1501A or an arrangement of distributed computer systems. The computer system 1501A includes one or more analysis module(s) 1502 configured to perform various tasks according to some embodiments, such as one or more methods disclosed herein. To perform these various tasks, the analysis module 1502 executes independently, or in coordination with, one or more processors 1504, which is (or are) connected to one or more storage media 1506. The processor(s) 1504 is (or are) also connected to a network interface 1507 to allow the computer system 1501A to communicate over a data network 1509 with one or more additional computer systems and/or computing systems, such as 1501B, 1501C, and/or 1501D (note that computer systems 1501B, 1501C and/or 1501D may or may not share the same architecture as computer system 1501A, and may be located in different physical locations, e.g., computer systems 1501A and 1501B may be located in a processing facility, while in communication with one or more computer systems such as 1501C and/or 1501D that are located in one or more data centers, and/or located in varying countries on different continents).

A processor can include a microprocessor, microcontroller, processor module or subsystem, programmable integrated circuit, programmable gate array, or another control or computing device.

The storage media 1506 can be implemented as one or more computer-readable or machine-readable storage media. Note that while in the example embodiment of FIG. 15 storage media 1506 is depicted as within computer system 1501A, in some embodiments, storage media 1506 may be distributed within and/or across multiple internal and/or external enclosures of computing system 1501A and/or additional computing systems. Storage media 1506 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLURAY® disks, or other types of optical storage, or other types of storage devices. Note that the instructions discussed above can be provided on one computer-readable or machine-readable storage medium, or alternatively, can be provided on multiple computer-readable or machine-readable storage media distributed in a large system having possibly plural nodes. Such computer-readable or machine-readable storage medium or media is (are) considered to be part of an article (or article of manufacture). An article or article of manufacture can refer to any manufactured single component or multiple components. The storage medium or media can be located either in the machine running the machine-readable instructions, or located at a remote site from which machine-readable instructions can be downloaded over a network for execution.

In some embodiments, computing system 1500 contains one or more seismic processing module(s) 1508. In the example of computing system 1500, computer system 1501A includes the seismic processing module 1508. In some embodiments, a single seismic processing module may be used to perform some or all aspects of one or more embodiments of the methods. In alternate embodiments, a plurality of seismic processing modules may be used to perform some or all aspects of methods.

It should be appreciated that computing system 1500 is only one example of a computing system, and that computing system 1500 may have more or fewer components than shown, may combine additional components not depicted in the example embodiment of FIG. 15, and/or computing system 1500 may have a different configuration or arrangement of the components depicted in FIG. 15. The various components shown in FIG. 15 may be implemented in hardware, software, or a combination of both hardware and software, including one or more signal processing and/or application specific integrated circuits.

Further, the steps in the processing methods described herein may be implemented by running one or more functional modules in information processing apparatus such as general purpose processors or application specific chips, such as ASICs, FPGAs, PLDs, or other appropriate devices. These modules, combinations of these modules, and/or their combination with general hardware are all included within the scope of protection of the invention.

Geologic interpretations, models and/or other interpretation aids may be refined in an iterative fashion; this concept is applicable to embodiments of the present methods discussed herein. This can include use of feedback loops executed on an algorithmic basis, such as at a computing device (e.g., computing system 1500, FIG. 15), and/or through manual control by a user who may make determinations regarding whether a given step, action, template, model, or set of curves has become sufficiently accurate for the evaluation of the subsurface three-dimensional geologic formation under consideration.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. Moreover, the order in which the elements of the methods are illustrated and described may be re-arranged, and/or two or more elements may occur simultaneously. The embodiments were chosen and described in order to best explain the principles of the invention and its practical applications, to thereby enable others skilled in the art to best utilize the invention and various embodiments with various modifications as are suited to the particular use contemplated.

What is claimed is:

1. A method for modeling a subsurface volume using time-lapse data, the method comprising:
receiving a baseline seismic dataset, a baseline property model, a monitoring seismic dataset, and a monitoring property model;
sorting the baseline seismic dataset and the monitoring seismic dataset into respective common gathers, representing offset, time, and depth point;
extracting signal data for a range of depth points for the baseline dataset and a signal data for a corresponding range of depth points for the monitoring seismic dataset;
predicting a property model change based at least in part on the signal data for the range of depth points of the baseline seismic dataset and the monitoring seismic dataset, using a machine learning model; and
generating a property model representing a subsurface volume based at least in part on the property model change predicted using the machine learning model.

2. The method of claim 1, wherein extracting the signal data comprises:
detecting a difference in a kinematic property, an amplitude, or both of the signal data for the range of depth points for the baseline dataset and the range of depth points for the monitoring dataset, wherein the machine learning model is trained to predict the property model change based at least in part on the difference in the kinematic property, the amplitude, or both.

3. The method of claim 1, comprising:
determining a training property difference between a portion of the baseline dataset and a corresponding portion of the monitoring dataset;
accessing a measured change in the property model corresponding to the portion;
generating a label based on a combination of the measured change and the training property difference; and
training the machine learning model based at least in part on the label.

4. The method of claim 1, wherein the signal data for the range of depth points for the baseline seismic dataset is input to the machine learning model as a first channel, and wherein the signal data for the range of depth points for the monitoring dataset is input to the machine learning model as a second channel, and wherein the machine learning model is trained to predict the property model change based on the first and second channels.

5. The method of claim 1, wherein range of depth points of the baseline dataset and the range of depth points of the monitoring dataset represent a same common depth point (CDP) range for the subsurface volume.

6. The method of claim 1, wherein the common gathers are common midpoint gathers.

7. The method of claim 1, wherein the property includes at least one of a kinematic difference or an amplitude difference.

8. The method of claim 1, wherein property model change is a CO2 property model change selected from the group consisting of density, acoustic impedance, shear wave velocity, and saturation.

9. The method of claim 1, wherein the baseline property model and the monitoring property model are both velocity models representing the subsurface volume, and wherein the baseline property model represents a velocity model that is not represented in the monitoring property model.

10. A computing system, comprising:
one or more processors; and
a memory system including one or more non-transitory, computer-readable media storing instructions that, when executed by at least one of the one or more processors, cause the computing system to perform operations, the operations including:
receiving a baseline seismic dataset, a baseline property model, a monitoring seismic dataset, and a monitoring property model;
sorting the baseline seismic dataset and the monitoring seismic dataset into respective common gathers, representing offset, time, and depth point;
extracting signal data for a range of depth points for the baseline dataset and a signal data for a corresponding range of depth points for the monitoring seismic dataset;
predicting a property model change based at least in part on the signal data for the range of depth points of the baseline seismic dataset and the monitoring seismic dataset, using a machine learning model; and
generating a property model representing a subsurface volume based at least in part on the property model change predicted using the machine learning model.

11. The computing system of claim 10, wherein extracting the signal data includes:
detecting a difference in a kinematic property, an amplitude, or both of the signal data for the range of depth points for the baseline dataset and the range of depth points for the monitoring dataset, wherein the machine learning model is trained to predict the property model change based at least in part on the difference in the kinematic property, the amplitude, or both.

12. The computing system of claim 10, wherein the operations include:
determining a training property difference between a portion of the baseline dataset and a corresponding portion of the monitoring dataset;
accessing a measured change in the property model corresponding to the portion;
generating a label based on a combination of the measured change and the training property difference; and
training the machine learning model based at least in part on the label.

13. The computing system of claim 10, wherein the signal data for the range of depth points for the baseline seismic dataset is input to the machine learning model as a first channel, and wherein the signal data for the range of depth points for the monitoring dataset is input to the machine learning model as a second channel, and wherein the machine learning model is trained to predict the property model change based on the first and second channels.

14. The computing system of claim 10, wherein the property includes at least one of a kinematic difference or an amplitude difference.

15. The computing system of claim 10, wherein property model change is a CO2 property model change selected from the group consisting of density, acoustic impedance, shear wave velocity, and saturation.

16. The computing system of claim 10, wherein the baseline property model and the monitoring property model are both velocity models representing the subsurface volume, and wherein the baseline property model represents a velocity model that is not represented in the monitoring property model.

17. A non-transitory, computer-readable medium storing instructions that, when executed by at least one processor of a computing system, cause the computing system to perform operations, the operations comprising:
receiving a baseline seismic dataset, a baseline property model, a monitoring seismic dataset, and a monitoring property model;
sorting the baseline seismic dataset and the monitoring seismic dataset into respective common gathers, representing offset, time, and depth point;
extracting signal data for a range of depth points for the baseline dataset and a signal data for a corresponding range of depth points for the monitoring seismic dataset;
predicting a property model change based at least in part on the signal data for the range of depth points of the baseline seismic dataset and the monitoring seismic dataset, using a machine learning model; and
generating a property model representing a subsurface volume based at least in part on the property model change predicted using the machine learning model.

18. The medium of claim 17, wherein extracting the signal data includes:
detecting a difference in a kinematic property, an amplitude, or both of the signal data for the range of depth points for the baseline dataset and the range of depth points for the monitoring dataset, wherein the machine learning model is trained to predict the property model change based at least in part on the difference in the kinematic property, the amplitude, or both.

19. The medium of claim 17, wherein the operations include:
determining a training property difference between a portion of the baseline dataset and a corresponding portion of the monitoring dataset;
accessing a measured change in the property model corresponding to the portion;
generating a label based on a combination of the measured change and the training property difference; and
training the machine learning model based at least in part on the label.

20. The medium of claim 17, wherein the signal data for the range of depth points for the baseline seismic dataset is input to the machine learning model as a first channel, and wherein the signal data for the range of depth points for the monitoring dataset is input to the machine learning model as a second channel, and wherein the machine learning model is trained to predict the property model change based on the first and second channels.
